(19) United States
(12) Patent Application Publication
(10) Pub. No.: US 2020/0028037 A1
(43) Pub. Date: Jan. 23, 2020

(54) MULTIPLE ENCAPSULATED LED ARRAYS ON A SINGLE PRINTED CIRCUIT BOARD (PCB)

(71) Applicant: Appleton Grp LLC, Rosemont, IL (US)

(72) Inventors: Sumit Kumar, Pune (IN); Milind Nimgulkar, Pune (IN); Ajay Tripathi, Libertyville, IL (US)

(21) Appl. No.: 16/379,257

(22) Filed: Apr. 9, 2019

(30) Foreign Application Priority Data
Jul. 19, 2018 (IN) 201821026970

(51) Int. Cl. H01L 33/54; H05K 1/02; H01L 33/58; H01L 33/08

(52) U.S. Cl. CPC H01L 33/54; H01L 33/08; H01L 33/58; H05K 1/0274

(57) ABSTRACT

Multiple encapsulated LED arrays on a single printed circuit board of an LED engine, the LED engine including a plurality of LED arrays that are mounted on the printed circuit board in a spaced apart configuration, and are electrically isolated from each other, and a plurality of encapsulation layers, wherein each of the encapsulation layers is configured to encapsulate each of the LED arrays, and is further configured to protect the area proximal to the LED engine from arc or spark generated by the LED engine, wherein each of the encapsulation layers includes a plurality of blisters that are configured to encapsulate at least one LED of an LED array, and is further configured to transform the light emitted by the LEDs into a desired light beam pattern, and at least one planar portion configured to encapsulate electrical traces formed on the printed circuit board.

### RELATED APPLICATIONS

This application claims priority to Indian Patent Application No. 201821026970 entitled “MULTIPLE ENCAPSULATED LED ARRAYS ON A SINGLE PRINTED CIRCUIT BOARD (PCB) FIELD” filed on Jul. 19, 2018, the contents of which are hereby incorporated by reference in their entirety.

The present disclosure relates to the field of luminaires. More particularly, the present disclosure relates to the field of LED engines used in luminaires.

### Definitions

As used in the present disclosure, the following terms are generally intended to have the meaning as set forth below, except to the extent that the context in which they are used indicates otherwise.

The expression “LED engine” used hereinafter in this specification refers to, but is not limited to an integrated assembly comprising LED arrays (modules), an LED driver, and other optical, thermal, mechanical and electrical components. More specifically, an LED engine consists of an LED chip mounted on a circuit board that has electrical connections and mechanical fixings and is ready to be fixed in a luminaire.

The expression “Zone-0” used hereinafter in this specification refers to, but is not limited to, an area in which an explosive atmosphere is present continuously for long periods of time or will frequently occur.

The expression “Zone-1” used hereinafter in this specification refers to, but is not limited to, an area in which an explosive atmosphere is likely to occur occasionally in normal operation. It may exist because of repair, maintenance operations, or leakage.

The expression “Zone-2” used hereinafter in this specification refers to, but is not limited to, an area in which an explosive atmosphere is not likely to occur in normal operation but, if it does occur, will persist for a short period only. These areas become hazardous only in an event of an accident or some unusual operating condition.

These definitions are in addition to those expressed in the art.

### BACKGROUND

The background information herein below relates to the present disclosure but is not necessarily prior art.

Lighting fixtures such as LED luminaires are widely used in many industrial environments. However, in industrial environments where an explosive atmosphere persists between 10 and 1000 hours a year due to the nature of the products being manufactured or processed, the electrical discharges are required to be tightly controlled in order to prevent explosions. It is mandatory to ensure that the electrical products used in such explosive atmospheres should eliminate the potential for electrical discharges such as sparks or arcs.

Conventionally, the lighting fixtures used in Zone-1 and Zone-0 applications are flame proof fixtures. These flame proof fixtures are usually heavy and bulky, which is not desired. Further, completely encapsulated LED engines were introduced, as an alternative to conventional flame proof structures and other known conventional techniques, for preventing electrical discharges considering the complexity and difficulty involved with other known conventional techniques.

However, in order to fulfill the requirement of the desired lumen output, multiple LED arrays are needed in a single LED engine of an LED luminaire, thereby increasing the number of interconnections required and the quantity of wires joined to light up the LED arrays. The increased number of interconnections and wiring also shrinks the reliability of the conventional encapsulated LED engine.

Further, in the conventional encapsulated LED engines, these multiple LED arrays are then encapsulated using a single encapsulation layer covering the entire printed circuit board which is not desired as it: increases the surface temperature of the LED engine, increases the cost of manufacturing the LED engine due to usage of more encapsulation material, and decreases the operating life of the LED engine. Additionally, the conventional encapsulated LED engines are also prone to early de-laminations, i.e., after around 50 to 60 cycles of thermal shocks.

Therefore, there is felt a need of an LED engine having multiple encapsulated LED arrays on a single printed circuit board of that alleviates the aforementioned problems and can be safely employed in hazardous environments.

### Objects

Some of the objects of the present disclosure, which at least one embodiment herein satisfies, are as follows.

It is an object of the present disclosure to ameliorate one or more problems of the prior art or to at least provide a useful alternative.

An object of the present disclosure is to provide an LED engine having multiple encapsulated LED arrays on a single printed circuit board.

Another object of the present disclosure is to provide an LED engine having multiple encapsulated LED arrays on a single printed circuit board, which is cost effective.

Still another object of the present disclosure is to provide an LED engine having multiple encapsulated LED arrays on a single printed circuit board, which has reduced surface temperature.

Yet another object of the present disclosure is to provide an LED engine having multiple encapsulated LED arrays on a single printed circuit board, which has a simple configuration.

Still another object of the present disclosure is to provide an LED engine having multiple encapsulated LED arrays on a single printed circuit board, which has improved life.

Yet another object of the present disclosure is to provide an LED engine having multiple encapsulated LED arrays on a single printed circuit board, that is not prone to early de-lamination due to frequent exposure to thermal shocks.

Still another object of the present disclosure is to provide an LED engine having multiple encapsulated LED arrays on a single printed circuit board, which eliminates the requirement of secondary optics.

Yet another object of the present disclosure is to provide an LED engine having multiple encapsulated LED arrays on a single printed circuit board, which is modular.

Still another object of the present disclosure is to provide an LED engine having multiple encapsulated LED arrays on a single printed circuit board, which better utilizes printed circuit board's space.

Yet another embodiment of the present disclosure is to provide an LED engine having multiple encapsulated LED arrays on a single printed circuit board, which eliminates formation of air bubbles between an operative top surface of a printed circuit board and an encapsulation layer.

Still another object of the present disclosure is to provide an LED engine having multiple encapsulated LED arrays on a single printed circuit board, which is light in weight.

Other objects and advantages of the present disclosure will be more apparent from the following description, which is not intended to limit the scope of the present disclosure.

### SUMMARY

The present disclosure envisages multiple encapsulated LED arrays on a single printed circuit board (PCB) of an LED engine. The LED engine comprises a plurality of LED arrays and a plurality of encapsulation layers.

Each of the plurality of LED arrays is mounted on the printed circuit board in a spaced apart configuration, and is electrically isolated from each other. Further, each of the encapsulation layers is configured to encapsulate each of the LED arrays, and is further configured to protect the area proximal to the LED engine from arc or spark generated by the engine. Each of the encapsulation layers includes a plurality of blisters and at least one planar portion.

At least one blister of the plurality of blisters is configured to encapsulate at least one LED of an LED array, and is further configured to transform the light emitted by the LEDs into a desired light beam pattern. Further, the planar portion of the encapsulation layer is configured to encapsulate electrical traces formed on the printed circuit board.

In an embodiment, the blisters have optical transmittance in the range of 90% to 96%.

In another embodiment, the thickness of the encapsulation layer is non-uniform. In still another embodiment, the thickness of the planar portion of the encapsulation layer is lesser than the thickness of the plurality of blisters of the encapsulation layer. In yet another embodiment, the thickness of the blisters is in the range of 2 mm to 6 mm and the thickness of the planar portion of the encapsulation layer is 3 mm.

In an embodiment, the LED engine is used for Zone-1 and Zone-2 applications.

In one embodiment, the material used for manufacturing the encapsulation layer is silicone.

In an embodiment, the encapsulation layer occupies an area in the range of 40% to 80% of the printed circuit board.

In another embodiment, the shape of the blisters is selected from the group consisting of circular, oval, eye-shaped, and elliptical.

In an embodiment, the blisters are configured to act as lenses for the LED array placed underneath the encapsulation layer.

### BRIEF DESCRIPTION OF THE ACCOMPANYING DRAWING

Multiple encapsulated LED arrays on a single printed circuit board (PCB) of an LED engine of the present disclosure will now be described with the help of the accompanying drawing, in which:

FIG. 1 illustrates an isometric view of multiple encapsulated LED arrays on a single printed circuit board (PCB) of an LED engine;

FIG. 2 illustrates an exploded view of the LED engine of FIG. 1;

FIG. 3 illustrates a top view of the LED engine of FIG. 1;

FIG. 4 illustrates a side view of the LED engine of FIG. 1; and

FIG. 5 illustrates a cross sectional side view of the LED engine of FIG. 1.

### LIST OF REFERENCE NUMERALS USED IN DETAILED DESCRIPTION AND DRAWING

100—LED engine
102—Encapsulation layer
104—Printed circuit board
106—Blisters
108—Planar portion
110—Elevated portion
112—Wires
114—LED array
114a—Light Emitting Diodes
114b—Electrical traces

### DETAILED DESCRIPTION

Conventionally, the entire printed circuit board of an LED engine is encapsulated which: increases the surface temperature of the LED engine, increases the cost of manufacturing the LED engine due to usage of more encapsulation material, and decreases the operating life of the LED engine. Additionally, the conventional encapsulated LED engines are also prone to early de-laminations, i.e., after around 50 to 60 cycles of thermal shocks.

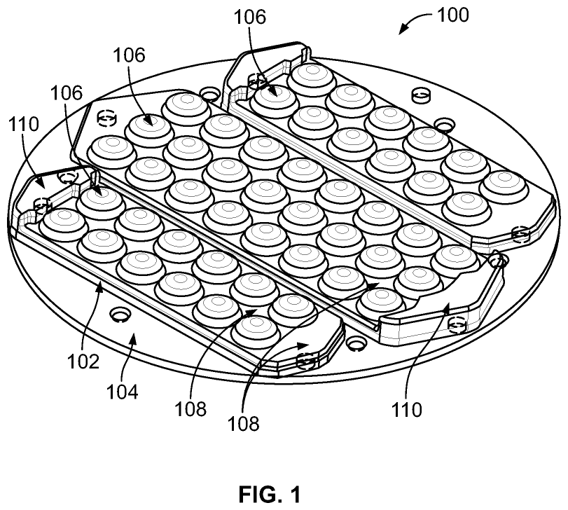

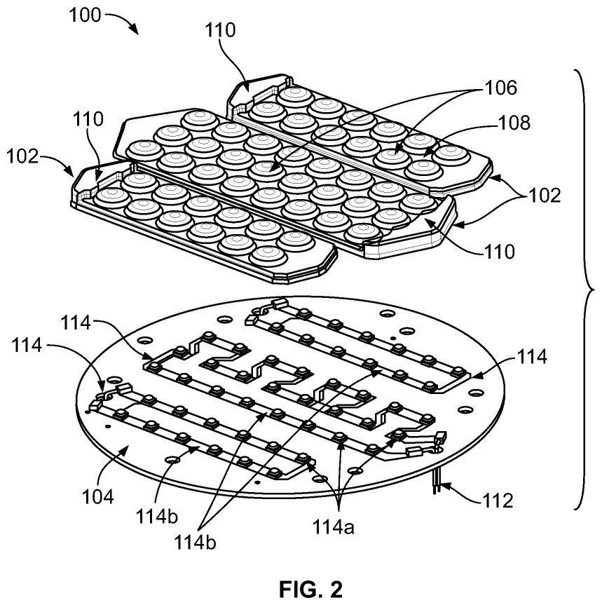

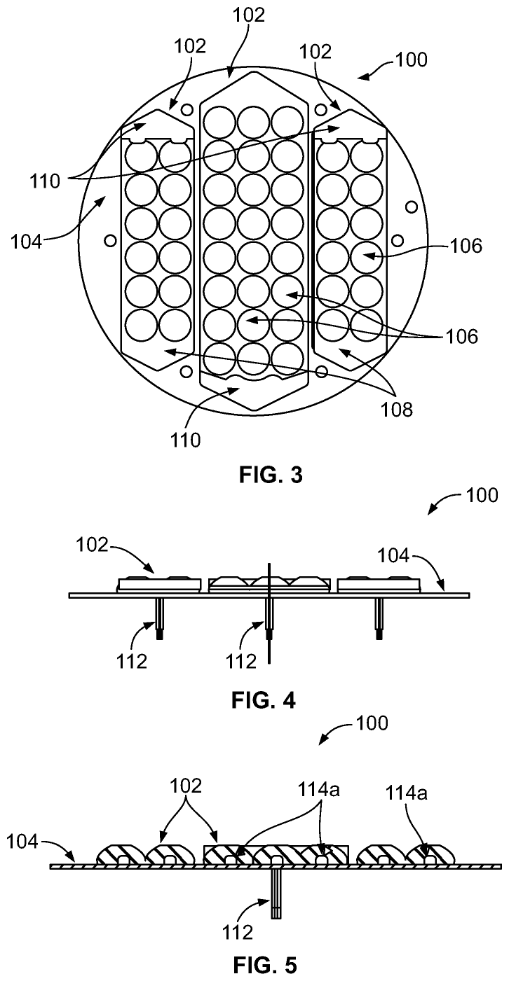

Multiple encapsulated LED arrays on a single printed circuit board (PCB) 104 of an LED (Light Emitting Diode) engine 100, of the present disclosure, is now being described with reference to FIG. 1 through FIG. 5. FIG. 1 illustrates an isometric view of multiple encapsulated LED arrays on a single printed circuit board (PCB) 104 of the LED engine 100. FIG. 2 illustrates an exploded view of the LED engine 100. FIG. 3 illustrates a top view of the LED engine 100. FIG. 4 illustrates a side view of the LED engine 100. FIG. 5 illustrates a cross sectional side view of the LED engine of FIG. 1.

The LED engine 100 (hereinafter also referred as “partially encapsulated LED engine”) comprises a plurality of LED arrays 114 and a plurality of encapsulation layers 102.

Each of the plurality of LED arrays 114 is mounted on the printed circuit board 104 in a spaced apart configuration, and is electrically isolated from each other. In an embodiment, the count of LED arrays 114 in the LED engine 100 is varied as per the required lumen output. In another embodiment, each of the plurality of LED arrays 114 contains a varied number of LEDs 114a. Further, each of the encapsulation layers 102 is configured to separately encapsulate each of the LED arrays 114 to protect the area proximal to the LED engine 100 from arc and spark, i.e., electrical discharges, generated by the LED engine 100. Each of the encapsulation layers 102 is molded such that it contains a plurality of blisters 106 and at least one planar portion 108.

At least one blister 106, of the plurality of blisters 106, is configured to encapsulate at least one LED 114a of the LED array 114. Further, the plurality of blisters 106 is also configured to function as lenses, i.e., as secondary optics, to facilitate transformation of the light emitted by the LEDs 114a, of the LED array 114, into a desired light beam pattern. In an embodiment, the blisters 106 have optical transmittance in the range of 90% to 96%.

The planar portion 108 of the encapsulation layer 102 is configured to encapsulate the electrical traces 114b formed on the printed circuit board 104. In an embodiment, the electrical traces 114b are configured to electrically connect LEDs 114b of the corresponding LED array 114.

In an embodiment, the thickness of the encapsulation layer 102 is non-uniform. In another embodiment, the thickness of the planar portion 108 of the encapsulation layer 102 is lesser than the thickness of the blisters 106 of the encapsulation layer 102. In yet another embodiment, the thickness of the blisters 106 and the planar portion 108 is in the range of 2 mm to 6 mm. In a preferred embodiment, the thickness of the planar portion 108 of the encapsulation layer 102 is 3 mm and the thickness of the blisters 106 is 3.5 mm.

In an embodiment, the LED engine 100 of the present disclosure is used for Zone-1 and Zone-2 applications. Specifically, in order to use the LED engine 100 for Zone-1 application, the thickness of the encapsulation layer 102 required is greater than or equal to 3 mm.

In one embodiment, the material used for manufacturing the encapsulation layer 102 is silicone.

In an embodiment, the encapsulation layer 102 occupies an area in the range of 40% to 80% of the printed circuit board 104.

In another embodiment, the shape of the blisters 106 is selected from the group consisting of circular, oval, eye-shaped, and elliptical.

In an embodiment, electrical wires 112 from each of the LED arrays 114 are guided through vias, i.e., through-holes of the printed circuit board 104. In another embodiment, the electrical wires 112 are soldered to the LED arrays 114 and the encapsulation layer 102 encapsulating the soldered region of the printed circuit board 104 is elevated.

A test for comparing the difference in surface temperature between the encapsulated LED engine 100, of the present disclosure, and the conventional completely encapsulated LED engine was performed.

Both of the partially encapsulated LED engine 100 and the completely encapsulated engine containing 50 light emitting diodes of the same type were continuously lit for 100 hours. It was observed that the surface temperature of the partially encapsulated LED engine was 115 degree Celsius whereas the surface temperature for the completely encapsulated LED engine was found to be 121.3 degree Celsius. Thus, it was observed that the partially encapsulated LED engine 100 was less heated as compared to the completely encapsulated LED engine 100.

Further, the ageing and de-lamination test was also performed on the partially encapsulated LED engine 100 and the completely encapsulated LED engine. The test was conducted using the thermal shock treatment in the temperature ranging from −50° C. to 140° C. It was observed that the completely encapsulated LED engine was de-laminated around 50 to 60 cycles of thermal shock, whereas no de-lamination was observed for the partially encapsulated LED engine 100 even after 500 cycles of thermal shocks.

In an embodiment, the LED engine 100 of the present disclosure better utilizes the space of the printed circuit board 104 having a circular profile. Additionally, partial encapsulation of the printed circuit board 104 also eliminates formation of air bubbles between the operative top surface of the printed circuit board 104 and the encapsulation layer 102.

### TECHNICAL ADVANCEMENTS

The present disclosure described herein above has several technical advantages including, but not limited to, the realization of multiple encapsulated LED arrays on a single printed circuit board of an LED engine that:
is cost effective;
has reduced surface temperature;
has simple configuration;
has improved life;
is not prone to early de-lamination due to frequent exposure to thermal shocks;
better utilizes printed circuit board's space;
eliminates formation of air bubbles;
is light in weight;
eliminates the requirement of secondary optics; and
is modular.

The embodiments herein and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the disclosure to achieve one or more of the desired objects or results.

Any discussion of documents, acts, materials, devices, articles or the like that has been included in this specification is solely for the purpose of providing a context for the disclosure. It is not to be taken as an admission that any or all of these matters form a part of the prior art base or were common general knowledge in the field relevant to the disclosure as it existed anywhere before the priority date of this application.

The numerical values mentioned for the various physical parameters, dimensions or quantities are only approximations and it is envisaged that the values higher/lower than the numerical values assigned to the parameters, dimensions or quantities fall within the scope of the disclosure, unless there is a statement in the specification specific to the contrary.

While considerable emphasis has been placed herein on the components and component parts of the preferred embodiments, it will be appreciated that many embodiments can be made and that many changes can be made in the preferred embodiments without departing from the principles of the disclosure. These and other changes in the preferred embodiment as well as other embodiments of the disclosure will be apparent to those skilled in the art from the disclosure herein, whereby it is to be distinctly understood that the foregoing descriptive matter is to be interpreted merely as illustrative of the disclosure and not as a limitation.

We claim:

1. Multiple encapsulated LED arrays on a single printed circuit board (104) of an LED engine (100), said LED engine (104) comprising:
a plurality of LED arrays (114), wherein each of said LED arrays (114) are mounted on said printed circuit board (104) in a spaced apart configuration, and are electrically isolated from each other; and
a plurality of encapsulation layers (102), wherein each of said encapsulation layers (102) is configured to encapsulate each of said LED arrays (114), and is further configured to protect the area proximal to said LED engine (100) from arc or spark generated by said LED engine (100), wherein
each of said encapsulation layers (102) including:
a plurality of blisters (106), wherein each of said blisters (106) is configured to encapsulate at least one LED (114a) of an LED array (114), and is further configured to transform the light emitted by said LEDs (114a) into a desired light beam pattern; and
at least one planar portion (108) configured to encapsulate electrical traces (114b) formed on said printed circuit board (104).

2. The LED engine (100) as claimed in claim 1, wherein said blisters (106) have optical transmittance in the range of 90% to 96%.

3. The LED engine (100) as claimed in claim 1, wherein the thickness of said encapsulation layer (102) is non-uniform.

4. The LED engine (100) as claimed in claim 1, wherein the thickness of said planar portion (108) of said encapsulation layer (102) is lesser than the thickness of the blisters (106) of said encapsulation layer (102).

5. The LED engine (100) as claimed in claim 1, wherein the thickness of said blisters (106) and said planar portion (108) is in the range of 2 mm to 6 mm.

6. The LED engine (100) as claimed in claim 1, wherein said LED engine (100) is used for Zone-1 and Zone-2 applications.

7. The LED engine (100) as claimed in claim 1, wherein the material used for manufacturing said encapsulation layer (102) is silicone.

8. The LED engine (100) as claimed in claim 1, wherein the encapsulation layers (102) occupy an area in the range of 40% to 80% of said printed circuit board (104).

9. The LED engine (100) as claimed in claim 1, wherein the shape of said blisters (106) is selected from the group consisting of circular, oval, eye-shaped, and elliptical.

10. The LED engine (100) as claimed in claim 1, wherein said blisters (106) are configured to act as lenses for said LED array (114) placed underneath said encapsulation layer (102).
